(19) United States
(12) Patent Application Publication
(10) Pub. No.: US 2026/0286832 A1
(43) Pub. Date: Sep. 24, 2026

(54) ENGINEERING BIONIC EXPERIMENTAL SYSTEM AND METHOD FOR EVALUATING ADAPTIVE BOREHOLE PLUGGING EFFECT BASED ON NMR

(71) Applicant: TAIYUAN UNIVERSITY OF TECHNOLOGY, Taiyuan (CN)

(72) Inventors: Zhen LI, Taiyuan (CN); Xiangming ZHANG, Taiyuan (CN); Yiming LIU, Taiyuan (CN); Yidie ZHANG, Taiyuan (CN); Guorui FENG, Taiyuan (CN); Ruping ZHANG, Taiyuan (CN); Shutong XUE, Taiyuan (CN); Junjie GAO, Taiyuan (CN); Haining XU, Taiyuan (CN); Zhenxing CHENG, Taiyuan (CN); Zhe QI, Taiyuan (CN); Guanyu ZHANG, Taiyuan (CN); Jun WANG, Taiyuan (CN)

(21) Appl. No.: 19/678,258

(22) Filed: May 15, 2026

(30) Foreign Application Priority Data
Aug. 14, 2025 (CN) 202511134338.0

(51) Int. Cl. E21B 47/005; E21B 43/00; G01N 24/08

(52) U.S. Cl. CPC E21B 47/005; G01N 24/081; E21B 43/006

(57) ABSTRACT

An engineering bionic experimental system for evaluating an adaptive borehole plugging effect based on nuclear magnetic resonance (NMR) is provided and includes a drilling device, a high-field NMR device, an ultrasonic tomography imaging device, a plugging device, and a confining-pressure heating and cooling circulation device. A method for evaluating an adaptive borehole plugging effect based on NMR is provided and includes: preparing a sample, forming an underground simulated field; performing real-time dynamic imaging of fracture evolution surrounding a borehole during drilling; performing a first plugging, dynamic imaging of fracture filling surrounding the borehole, and a plugging effect evaluation, adjusting parameters of the underground simulated field to cause the first plugging to fail and to induce generation of new fractures or propagation of pre-existing fractures surrounding the plugged borehole; performing a secondary plugging; and repeating the above steps.

### CROSS-REFERENCE TO RELATED APPLICATIONS

This application claims the benefit of priority from Chinese Patent Application No. 202511134338.0, filed on Aug. 14, 2025. The content of the aforementioned application, including any intervening amendments thereto, is incorporated herein by reference in its entirety.

### TECHNICAL FIELD

This application relates to the field of gas extraction and borehole plugging, and more particularly, to an engineering bionic experimental system and method for evaluating an adaptive borehole plugging effect based on nuclear magnetic resonance (NMR).

### BACKGROUND

Coalbed methane (CBM) is an unconventional natural gas resource with substantial domestic reserves, estimated at approximately 36.8 trillion cubic meters. However, the current development and utilization volume of CBM remains below 1% of the proven reserves. Methane, the primary component of CBM, has a greenhouse effect approximately twenty times that of CO₂ and contributes to ozone layer depletion at a rate approximately seven times that of CO₂. Therefore, the rational development and utilization of methane are of great significance for ecological and environmental protection.

During roadway excavation and the construction of gas extraction boreholes, stress concentrations commonly occur, resulting in damage to the coal surrounding boreholes. Such damage generates fractures of varying scales around roadways and the boreholes, through which gas contained within the coal seam can migrate. Macroscopic fractures and microscopic fractures together form a fracture network. Under continued mining-induced stress disturbances and sustained gas extraction, the fracture network evolves dynamically: the number of fractures increases, fracture apertures vary, and the gas pressure surrounding the boreholes correspondingly fluctuates. These fractures provide seepage pathways that allow air from the roadways to enter the boreholes, resulting in a significant decrease in the gas extraction concentration.

To address the need for plugging micro-fractures surrounding the boreholes, extensive research has been conducted on dynamic plugging materials such as gel materials, polymer materials, and novel non-solid materials. The effectiveness of these plugging materials is typically evaluated through the gas concentration monitoring, the pressure differential analysis, and the plugging material property testing.

However, the prior art suffers from the following deficiencies:
1. limited evaluation dimensions and lack of real-time visualization during plugging: existing methods primarily rely on indirect parameters, such as gas concentration, pressure, and water retention, to evaluate the plugging effect, and are unable to directly and in real time visualize the diffusion pathways of the plugging material within the surrounding fractures or assess the plugging density;
2. inability to simulate dynamic fracture evolution during the drilling: the existing experimental devices are incapable of simulating dynamic imaging of the full fracture evolution process occurring around the boreholes during the in-situ borehole construction; and
3. insufficient bionic adaptability between the existing experimental devices and the actual plugging processes: borehole plugging is influenced by multi-field coupling effects, including the in-situ stress, the geothermal conditions, and the gas pressure. The existing experimental devices are incapable of simulating and revealing the interaction mechanisms between the plugging material and the coal under complex multi-field coupling conditions.

Accordingly, there is a need for an experimental system that integrates multi-field coupling simulation, engineering bionic design, and high-precision dynamic monitoring technology. Such a system enables investigation of the real-time evolution of the fractures surrounding the boreholes during drilling, visualization of the flow behavior of the plugging material within the fractures during initial plugging, and visualization of the dynamic evolution of the fractures during repeated plugging under multi-field coupling conditions. In this way, the system can provide reference data for determining the length of a borehole plugging section, identify potential deficiencies of the plugging material under realistic conditions in advance, shorten the verification cycle from laboratory testing to field application, and provide high-resolution dynamic fracture network data to support digital twin technologies for intelligent borehole plugging.

### SUMMARY

The present disclosure addresses the foregoing deficiencies and provide an engineering bionic experimental system for evaluating the adaptive borehole plugging effect based on NMR. The engineering bionic experimental system enables visualization of the real-time dynamic evolution of fractures surrounding boreholes during drilling, visualization of flow and filling processes of a plugging material within the fractures surrounding the boreholes during repeated plugging operations, and investigation of interaction mechanisms between the plugging material and the coal under multi-field coupling conditions.

To achieve the above objectives, the present disclosure provides an engineering bionic experimental system for evaluating an adaptive borehole plugging effect based on NMR. The engineering bionic experimental system includes a drilling device, a high-field NMR device, an ultrasonic tomography imaging device, a plugging device, and a confining-pressure heating and cooling circulation device. The drilling device comprises a drill rod and a drill bit provided at one end of the drill rod. The high-field NMR device comprises a cylindrical housing. The cylindrical housing comprises an inner fiberglass epoxy resin tube and an outer fiberglass epoxy resin tube sleeved together, a plurality of radio-frequency coils are bonded to an outer side of the inner fiberglass epoxy resin tube and configured to generate a radio-frequency magnetic field, a plurality of gradient coils are mounted on the outer fiberglass epoxy resin tube and configured to generate a static magnetic field, and a sample holder capable of applying pressure is provided within an internal cavity of the inner fiberglass epoxy resin tube. The sample holder comprises a clamping cylinder, wherein the clamping cylinder is hollow and non-magnetic, and both ends of the clamping cylinder are open, wherein a plurality of retractable sample supports are arranged at a lower end of a middle portion of an inner side of the clamping cylinder, a confining-pressure fluid inlet is provided at a lower portion of a left end of the clamping cylinder, and a confining-pressure fluid outlet is provided at an upper portion of a right end of the clamping cylinder. An axial loading device for applying pressure to a coal body is mounted inside the clamping cylinder, wherein the axial loading device comprises an annular pressure plate and a perforated circular pressure plate respectively provided at both ends of the clamping cylinder. A plugging cover is provided in a hollow portion of the annular pressure plate, wherein the plugging cover defines a seepage hole at a center of the plugging cover. A first sample fixer is mounted on an inner side surface of the annular pressure plate, a second sample fixer is mounted on an inner side surface of the perforated circular pressure plate, and the first sample fixer and the second sample fixer are positioned at a same horizontal height. A plurality of axial pressing rods are respectively mounted on an outer side surface of the annular pressure plate and an outer side surface of the perforated circular pressure plate. A T-shaped three-way pipe is threadedly connected to a center hole of the perforated circular pressure plate, and an electric throttle valve is provided on the T-shaped three-way pipe. The ultrasonic tomography imaging device comprises a plurality of transmitting transducers, a plurality of transmitting amplifiers, and a plurality of receiving transducers, wherein the plurality of transmitting amplifiers are circumferentially and uniformly arranged on the outer side surface of the annular pressure plate, the plurality of transmitting transducers overlap and are mounted on the plurality of transmitting amplifiers, and the plurality of receiving transducers are arranged on the outer side surface of the perforated circular pressure plate at positions corresponding to the plurality of transmitting amplifiers. The plugging device comprises two plugging bags, wherein a plugging section is provided between and connected to the two plugging bags, a feeding pipe is in communication with the two plugging bags, the feeding pipe defines injection holes in portions of the feeding pipe located within the two plugging bags, rupture valves are respectively arranged on surfaces of the two plugging bags and opposite to each other, and a feeding end of the feeding pipe is sequentially connected, in order from a position closer to the two plugging bags to a position farther away from the two plugging bags, to a first pressure-retaining valve, a constant-pressure intelligent grouting pump, and a plugging material storage tank. The confining-pressure heating and cooling circulation device comprises a second pressure-retaining valve, a confining-pressure fluid heater, a confining-pressure fluid injection pump, a confining-pressure fluid storage tank, a confining-pressure fluid cooler, an accumulator, and a third pressure-retaining valve, sequentially connected through an insulated thermal pipe. The second pressure-retaining valve is connected to the confining-pressure fluid inlet through the insulated thermal pipe. The third pressure-retaining valve is connected to the confining-pressure fluid outlet through the insulated thermal pipe. The confining-pressure fluid storage tank, the confining-pressure fluid injection pump, and the confining-pressure fluid heater are respectively connected to a data acquisition device through control lines, wherein the data acquisition device is electrically connected to a control system and is configured to acquire, in real time, data indicative of a remaining fluid volume in the confining-pressure fluid storage tank, a flow rate and a pressure of the confining-pressure fluid injection pump, and a temperature of the confining-pressure fluid heater, and to transmit the data to the control system.

In the embodiments of the present disclosure, the drill rod defines a central bore extending along an axial centerline of the drill rod, and has wide-tooth groove threads extending from an outer surface of the drill rod toward an interior of the drill rod. The drill bit comprises four obliquely columnar cutters symmetrically arranged on an end surface of the drill rod, wherein a plurality of claw-type atomizing nozzles are mounted on inner sides of the four obliquely columnar cutters, and each of the plurality of claw-type atomizing nozzles has one end in communication with the central bore of the drill rod and another end facing toward a corresponding one of the four obliquely columnar cutters.

In the embodiments of the present disclosure, the plurality of radio-frequency coils are uniformly bonded to the outer side of the inner fiberglass epoxy resin tube, a capacitor is welded between each two adjacent radio-frequency coils among the plurality of radio-frequency coils to store energy and adjust a coil frequency, and an inductance plate, a circuit splitter, and cables are mounted in electrical communication with the plurality of radio-frequency coils. The outer fiberglass epoxy resin tube defines annular grooves, wherein the plurality of gradient coils are uniformly attached and bonded within the annular grooves, and cooling tubes are wound around the plurality of gradient coils to absorb heat generated by the plurality of gradient coils. The inner fiberglass epoxy resin tube attached with the plurality of radio-frequency coils is inserted into the outer fiberglass epoxy resin tube attached with the plurality of gradient coils, and liquid nitrogen is filled and sealed in a space between the inner fiberglass epoxy resin tube and the outer fiberglass epoxy resin tube.

In the embodiments of the present disclosure, a first axial pressing rod, a second axial pressing rod, a third axial pressing rod, and a fourth axial pressing rod, each parallel to a central axis of the clamping cylinder, are welded onto the outer side surface of the annular pressure plate. A fifth axial pressing rod, a sixth axial pressing rod, a seventh axial pressing rod, and an eighth axial pressing rod, each parallel to the central axis of the clamping cylinder, are welded onto the outer side surface of the perforated circular pressure plate.

In the embodiments of the present disclosure, a circular rubber gasket is provided on an inner side of the first sample fixer, and a perforated rubber gasket is provided on an inner side of the second sample fixer.

In the embodiments of the present disclosure, the plurality of transmitting transducers comprise eight transmitting transducers, the plurality of transmitting amplifiers comprise eight transmitting amplifiers, and the plurality of receiving transducers comprise eight receiving transducers. The eight transmitting amplifiers are circumferentially arranged on an outer peripheral surface of the annular pressure plate at angular positions of 30°, 60°, 120°, 150°, 210°, 240°, 300°, and 330°. The eight receiving transducers are arranged on the perforated circular pressure plate at positions corresponding to the eight transmitting amplifiers.

In the embodiments of the present disclosure, the confining-pressure fluid injection pump has a pressure adjustment range of 0-60 MPa and an adjustment precision of 0.10 MPa. The confining-pressure fluid heater has a temperature control range of 0-70° C., a heating rate of ≥10 ° C./min, and a temperature control precision of 0.01° C. The confining-pressure fluid cooler is provided internally with a temperature measuring device configured to measure an input fluid temperature. The confining-pressure fluid cooler is further provided internally with a condenser pipe and a refrigerant, wherein the refrigerant is carbon dioxide R744, and the confining-pressure fluid cooler has a temperature control range of 0-40° C. and a cooling rate of ≥10 ° C./min.

The present disclosure further provides a method for evaluating an adaptive borehole plugging effect based on nuclear magnetic resonance (NMR), performed by the above engineering bionic experimental system, comprising:
(S1) preparing a sample, comprising:
   obtaining an intact coal body sample from an underground mine;
   polishing the intact coal body sample to match dimensions of the clamping cylinder to obtain the coal body;
   sleeving a thermoplastic sleeve on the coal body, wherein a length of the thermoplastic sleeve is greater than a length of the coal body;
   placing the coal body wrapped in the thermoplastic sleeve into the clamping cylinder and on the plurality of retractable sample supports;
   adjusting heights of the plurality of retractable sample supports such that both ends of the coal body respectively align with the first sample fixer and the second sample fixer; and
   adjusting the axial loading device to clamp the coal body;
(S2) forming an underground simulated field, comprising:
   determining an axial pressing stress, a confining pressure, a gas injection amount, and a confining-pressure fluid temperature according to ground stress parameters, gas content and pressure parameters, and a temperature of the underground mine;
   activating the axial loading device to apply the axial pressing stress at a loading rate of 0.1 mm/min until the axial pressing stress reaches a preset pre-stress; activating the confining-pressure fluid injection pump to establish an initial confining pressure and inject a confining-pressure fluid;
   activating the confining-pressure fluid heater, recording an initial temperature t₁ of the confining-pressure fluid prior to heating, and setting a preliminary heating setpoint t₂ as a heating setpoint of the confining-pressure fluid heater for heating the confining-pressure fluid;
   activating the confining-pressure fluid cooler and recording a temperature-versus-time curve of the confining-pressure fluid discharged from the confining-pressure fluid cooler;
   after temperature fluctuations of the temperature-versus-time curve fall within a predetermined tolerance range, determining a stabilized temperature value t₃ of the temperature-versus-time curve;
   calculating a temperature difference Δt=t₃−t₂ and transmitting the temperature difference Δt to a computer to calculate a heat loss;
   adjusting the heating setpoint of the confining-pressure fluid heater from the preliminary heating temperature t₂ to a calibrated heating temperature t₄ based on the heat loss, such that an internal temperature of the coal body reaches a preset temperature t₀;
   increasing the axial pressing stress and the confining pressure to simulate actual underground pressure conditions; and
   introducing gas into the coal body through the T-shaped three-way pipe, allowing the gas to exit through the seepage hole of the plugging cover, and maintaining gas injection for 48 hours;
(S3) performing real-time dynamic imaging of fracture evolution surrounding a borehole during drilling, comprising:
   removing the plugging cover;
   activating the high-field NMR device and, after the static magnetic field reaches a stable field strength and a magnetic field homogeneity calibration is completed, setting a resonance frequency, a spectral width, a number of sampling points, a number of accumulations, a relaxation delay, and a pulse sequence;
   after the high-field NMR device has operated normally for a period of time, activating the drilling device to form the borehole along an axial center of the coal body;
   during advancement of the drill bit, continuously acquiring, by the high-field NMR device, a T₂-weighted transverse relaxation time signal of ¹H nuclei in fracture water of the coal body surrounding the borehole, and performing real-time imaging to visualize dynamic evolution of a fracture network surrounding the borehole;
   after completion of the drilling, recording the T₂-weighted transverse relaxation time signal of ¹H nuclei in the fracture water acquired by the high-field NMR device as a data set Q₁;
   processing the data set Q₁ through image processing and three-dimensional reconstruction to obtain a three-dimensional fracture structure D₁;
   determining a maximum axial length L₀ of the fracture network based on the three-dimensional fracture structure D₁; and
   determining a length L of the plugging section according to the maximum axial length L₀;
   (S4) performing a first plugging, dynamic imaging of fracture filling surrounding the borehole, and a plugging effect evaluation, comprising:
   after completion of the drilling, sealing openings of the borehole using the plugging cover;
   after sealing the openings of the borehole, increasing the temperature of the confining-pressure fluid heater to heat the confining-pressure fluid for a period of time, thereby drying internal moisture of the coal body through thermal conduction of the confining-pressure fluid until imaging by the high-field NMR device is no longer obtainable;
   connecting the two plugging bags and the feeding pipe according to the length L of the plugging section determined at step (S3);
   after connecting the two plugging bags and the feeding pipe, removing the plugging cover and inserting the two plugging bag) and the feeding pipe into the borehole;
   activating the constant-pressure intelligent grouting pump, setting an initial grouting pressure, and injecting a plugging material into the two plugging bags and the borehole;
   monitoring the high-field NMR device and, after two elliptical high-intensity NMR signal regions indicative of plugging bag inflation are formed, increasing a grouting pressure to rupture the rupture valves;
   after the plugging material flows into the plugging section, maintaining a constant grouting pressure and continuously injecting the plugging material until the borehole is completely filled;
   determining, through the real-time imaging, migrations of the plugging material within the borehole;
   acquiring, by the high-field NMR device, a T₂-weighted transverse relaxation time signal of ¹H nuclei in water of the plugging material, and recording the T₂-weighted transverse relaxation time signal of ¹H nuclei in the water of the plugging material as a data set Q₂;
   processing the data set Q₂ through image processing and three-dimensional reconstruction to obtain a visualized three-dimensional fracture structure D₂;
   comparing the data set Q₁ with the data set Q₂ to determine an overlap ratio between the data set Q₁ and the data set Q₂; and
   determining whether a ratio of the three-dimensional fracture structure D₁ to the visualized three-dimensional fracture structure D₂ falls within a tolerance range according to the overlap ratio between the data set Q₁ and the data set Q₂;
(S5) adjusting parameters of the underground simulated field to cause the first plugging to fail and to induce generation of new fractures or propagation of pre-existing fractures surrounding the plugged borehole, comprising:
   activating the ultrasonic tomography imaging device;
   connecting a transducer array to a data acquisition module of the ultrasonic tomography imaging device;
   setting transmission parameters comprising a transmission voltage, a pulse bandwidth or waveform, an imaging speed, and a center frequency of a transducer;
   setting reception parameters comprising a sampling rate, a gain, and a data storage format;
   configuring channels for bidirectional transmission;
   adjusting the confining pressure, the axial pressing stress, and a gas pressure to induce the generation of the new fractures or the propagation of the pre-existing fractures surrounding the plugged borehole;
   activating transmitters in a predetermined sequence to perform tomographic scanning and data acquisition;
   extracting propagation time and amplitude data of fracture initiation and propagation;
   reconstructing a sound velocity distribution map;
   marking sound velocity anomaly regions, wherein a spatial region is determined as a new fracture when a decrease in acoustic velocity of ≥5% is detected in the spatial region in at least three consecutive reconstructed tomographic frames acquired at a predetermined sampling frequency;
   stacking two-dimensional images of all layers to form a three-dimensional voxel image;
   rendering and analyzing fracture structures to obtain a three-dimensional image and a data set W₁; and
   transmitting ultrasonic tomography imaging data acquired by the ultrasonic tomography imaging device to the computer;
(S6) performing a secondary plugging, comprising:
   comparing, by the computer, real-time NMR imaging data with the ultrasonic tomography imaging data of the new fractures transmitted at step (S5);
   determining, by comparing the data set Q₂ and the data set W₁, a number of the new fractures and a void volume of apertures of the new fractures;
   determining an amount of a required plugging material according to the number of the new fractures and the void volume of the apertures of the new fractures, so as to prevent excessive grouting pressure from inducing hydraulic fracturing of the coal body;
   controlling, by the computer, the plugging device to inject the required plugging material into the borehole;
   performing real-time NMR imaging to visualize filling of the new fractures, the propagation of pre-existing fractures, or the fracture network, thereby acquiring the real-time NMR imaging data;
   comparing the real-time NMR imaging data with the ultrasonic tomography imaging data obtained at step (S5); and
   calculating a plugging density to evaluate a plugging effect;
(S7) repeating steps (S5) and (S6) to implement an adaptive plugging process comprising plugging, plugging failure, and re-plugging under various ground stress conditions, geothermal environments, and gas pressures, thereby evaluating the adaptive borehole plugging effect.

Compared with the prior art, the present disclosure provides the following advantageous effects:
(1) full-lifecycle dynamic monitoring: the present disclosure achieves in-situ NMR characterization throughout the entire borehole lifecycle, including: imaging of the dynamic evolution of the fractures surrounding the borehole during drilling; dynamic plugging of the fractures after borehole formation; plugging failure under multi-field coupling conditions; and subsequent re-plugging. This enables an adaptive borehole plugging process and a plugging effect evaluation;
(2) plugging effect evaluation based on multi-source signals: in contrast to conventional single-parameter and indirect evaluation methods, the present disclosure provides real-time visualization of the flow state of the plugging material within the borehole, provides imaging of plugging of the fractures surrounding the borehole, directly and accurately illustrates the fracture filling process and the resulting filling density, thereby eliminating interference from other factors that may cause reductions in gas concentration or pressure; and
(3) enhanced bionic adaptability between laboratory testing and field application: by simulating the coupled effects of in-situ stress, gas pressure, geothermal conditions, and their interactions with the plugging material, the system can identify potential deficiencies of the plugging material under realistic operating environments in advance, shorten the material optimization and validation cycle, and reduce on-site implementation costs.

### BRIEF DESCRIPTION OF THE DRAWINGS

FIG. 1 is a schematic structural diagram of a drilling device according to the present disclosure.

FIG. 2 is a side view of a drill bit.

FIG. 3 is a schematic structural diagram of a high-field NMR device according to the present disclosure.

FIG. 4 is a schematic structural diagram of an ultrasonic tomography imaging device according to the present disclosure.

FIG. 5 is a schematic structural diagram of a plugging device according to the present disclosure.

FIG. 6 is a schematic structural diagram of a confining-pressure heating and cooling circulation device according to the present disclosure.

FIG. 7 illustrates a propagation process of fractures in a coal body during drilling according to the present disclosure.

FIG. 8 is a schematic diagram of plugging fractures surrounding a borehole in a coal body according to the present disclosure.

FIG. 9 illustrates a side view of an axial loading device and a schematic diagram of installation of an ultrasonic tomography imaging device according to the present disclosure.

### REFERENCE NUMERALS IN THE FIGURES

1-1, drill rod; 1-2, drill bit; 1-3, claw-type atomizing nozzle; 1-4, wide-tooth groove thread; 1-5, obliquely columnar cutter; 1-6, borehole; 2-1, clamping cylinder; 2-2, retractable sample support; 2-3, confining-pressure fluid inlet; 2-4, confining-pressure fluid outlet; 2-5, thermoplastic sleeve; 2-6, annular pressure plate; 2-7, plugging cover; 2-8, seepage hole; 2-9, first axial pressing rod; 2-10, second axial pressing rod; 2-11, third axial pressing rod; 2-12, fourth axial pressing rod; 2-13, first sample fixer; 2-14, circular rubber gasket; 2-15, perforated circular pressure plate; 2-16, fifth axial pressing rod; 2-17, sixth axial pressing rod; 2-18, seventh axial pressing rod; 2-19, eighth axial pressing rod; 2-20, second sample fixer; 2-21, perforated rubber gasket; 2-22, T-shaped three-way pipe; 2-23, radio-frequency coil; 2-24, gradient coil; 3-1, transmitting transducer; 3-2, transmitting amplifier; 3-3, receiving transducer; 4-1, plugging material storage tank; 4-2, constant-pressure intelligent grouting pump; 4-3, first pressure-retaining valve; 4-4, feeding pipe; 4-5, plugging bag; 4-6, injection hole; 4-7, rupture valve; 4-8, plugging section; 5-1, confining-pressure fluid storage tank; 5-2, confining-pressure fluid injection pump; 5-3, confining-pressure fluid heater; 5-4, second pressure-retaining valve; 5-5, third pressure-retaining valve; 5-6, accumulator; 5-7, confining-pressure fluid cooler; 5-8, insulated thermal pipe; 6, coal body; 7, filled fracture.

### DETAILED DESCRIPTION OF EMBODIMENTS

The present disclosure will be further described below with reference to specific embodiments.

### Embodiment 1

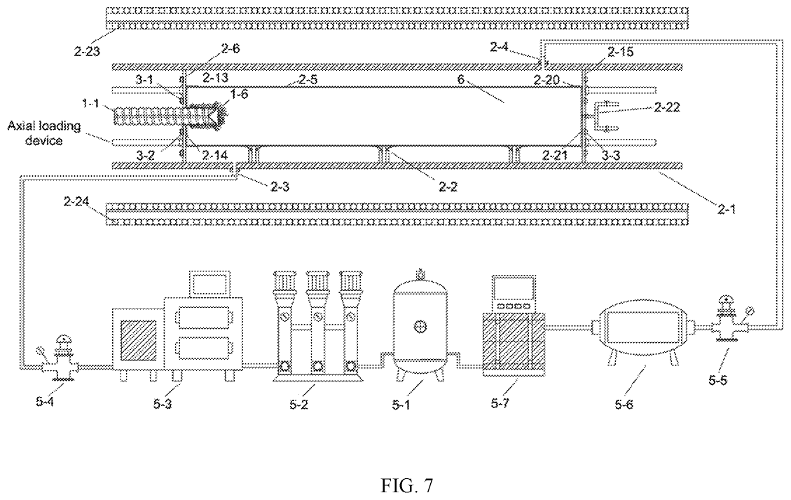

As shown in FIG. 7, an engineering bionic experimental system for evaluating an adaptive borehole plugging effect based on nuclear magnetic resonance (NMR) includes a drilling device, a high-field NMR device, an ultrasonic tomography imaging device, a plugging device, and a confining-pressure heating and cooling circulation device.

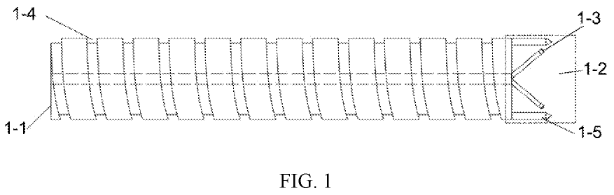

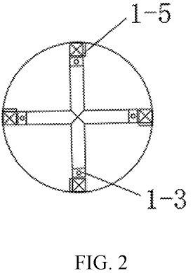

As shown in FIG. 1, the drilling device includes a drill rod 1-1, and a drill bit 1-2 is provided at one end of the drill rod 1-1. The drill rod 1-1 has a hollow structure extending along an axial centerline of the drill rod 1-1, namely, a central bore is defined in the drill rod 1-1. The drill rod 1-1 has wide-tooth groove threads 1-4 extending from an outer surface of the drill rod 1-1 toward an interior of the drill rod 1-1. During drilling, fragmented coal particles are conveyed out of the borehole through the wide-tooth groove threads 1-4. As shown in FIG. 2, the drill bit 1-2 includes four obliquely columnar cutters 1-5 symmetrically arranged on an end surface of the drill rod 1-1. A claw-type atomizing nozzle 1-3 is correspondingly mounted on an inner side of each obliquely columnar cutter 1-5. One end of each claw-type atomizing nozzle 1-3 is in communication with the central bore of the drill rod 1-1, and another end of each claw-type atomizing nozzle 1-3 faces toward a corresponding obliquely columnar cutter 1-5. The obliquely columnar cutters 1-5 are made of polycrystalline diamond composite sheets, and an inclination direction thereof is consistent with a drilling direction. Each claw-type atomizing nozzle 1-3 is threadably secured to one end of the drill bit 1-2, and has a designed size smaller than a diameter of the drill rod.

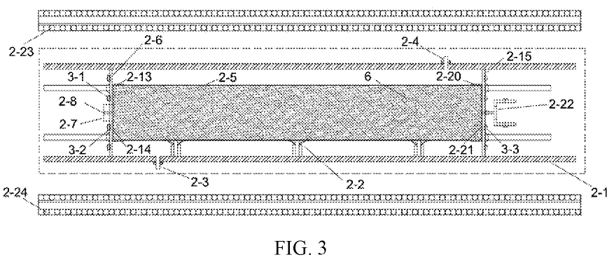

As shown in FIG. 3, the high-field NMR device includes a cylindrical housing formed by sleeving together an inner fiberglass epoxy resin tube and an outer fiberglass epoxy resin tube. A plurality of radio-frequency coils 2-23 are bonded to an outer side of the inner fiberglass epoxy resin tube and configured to generate a radio-frequency magnetic field. A plurality of gradient coils 2-24 are mounted on the outer fiberglass epoxy resin tube and configured to generate a static magnetic field. A capacitor is welded between each two adjacent radio-frequency coils 2-23 to store energy and adjust a coil frequency, and an inductance plate, a circuit splitter, and cables are mounted in electrical communication with the plurality of radio-frequency coils 2-23. The outer fiberglass epoxy resin tube defines annular grooves. A plurality of gradient coils 2-24 are uniformly attached and bonded within the annular grooves. Cooling tubes are wound around the gradient coils 2-24 to absorb heat generated by the gradient coils. The inner fiberglass epoxy resin tube attached with the radio-frequency coils 2-23 is inserted into the outer fiberglass epoxy resin tube attached with the gradient coils 2-24. Liquid nitrogen is filled and sealed in a space between the inner fiberglass epoxy resin tube and the outer fiberglass epoxy resin tube so that the high-field NMR device is maintained in an ultra-low-temperature environment of approximately 4 K. Upon energization, the gradient coils 2-24 form a superconducting magnet. After power-on and frequency tuning, a static magnetic field is generated within an internal chamber. A sample holder capable of applying pressure is provided within an internal cavity of the inner fiberglass epoxy resin tube. The sample holder is delivered into the magnetic field along a guide rail and is suspended therein. The sample holder includes a clamping cylinder 2-1, which is hollow, non-magnetic, mechanically strong, and open at both ends. A maximum confining pressure resistance of the clamping cylinder 2-1 is 120 MPa, and an inner wall of the clamping cylinder 2-1 is smoothly finished. A plurality of retractable sample supports 2-2 are arranged at a lower end of a middle portion of an inner side of the clamping cylinder 2-1. The retractable sample supports 2-2 are made of carbon fiber and have a load capacity of ≥10 kN. A confining-pressure fluid inlet 2-3 is provided at a lower portion of a left end of the clamping cylinder 2-1, and a confining-pressure fluid outlet 2-4 is provided at an upper portion of a right end of the clamping cylinder 2-1. The confining-pressure fluid inlet 2-3 and the confining-pressure fluid outlet 2-4 are each connected to the confining-pressure heating and cooling circulation device through a sealing gasket and a threaded nut. An axial loading device for applying pressure to the coal body is further mounted inside the clamping cylinder 2-1. The axial loading device has a loading range of 0-500 kN and a loading rate adjustable from 0 to 50 mm/min.

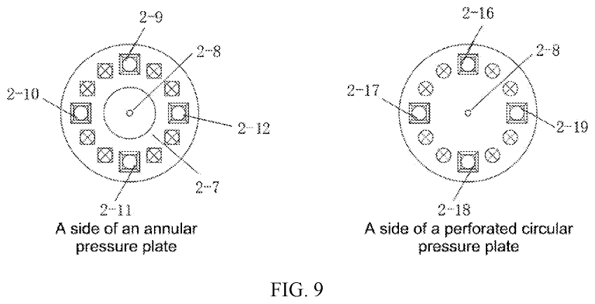

The axial loading device includes an annular pressure plate 2-6 and a perforated circular pressure plate 2-15 respectively disposed at both ends of the clamping cylinder 2-1. A plugging cover 2-7 is provided in a hollow portion of the annular pressure plate 2-6, and a seepage hole 2-8 is defined at a center of the plugging cover 2-7. A first sample fixer 2-13 and a second sample fixer 2-20 are respectively mounted on inner side surfaces of the annular pressure plate 2-6 and the perforated circular pressure plate 2-15 at a same horizontal height. The inner side surfaces refer to surfaces facing toward the coal body. A first axial pressing rod 2-9, a second axial pressing rod 2-10, a third axial pressing rod 2-11, and a fourth axial pressing rod 2-12, each parallel to a central axis of the clamping cylinder 2-1, are welded onto an outer side surface of the annular pressure plate 2-6, as shown in FIG. 9. A fifth axial pressing rod 2-16, a sixth axial pressing rod 2-17, a seventh axial pressing rod 2-18, and an eighth axial pressing rod 2-19, each parallel to the central axis of the clamping cylinder 2-1, are welded onto an outer side surface of the perforated circular pressure plate 2-15, as shown in FIG. 9. A T-shaped three-way pipe 2-22 is threadably connected to a center hole of the perforated circular pressure plate 2-15, and an electric throttle valve is provided on the T-shaped three-way pipe 2-22.

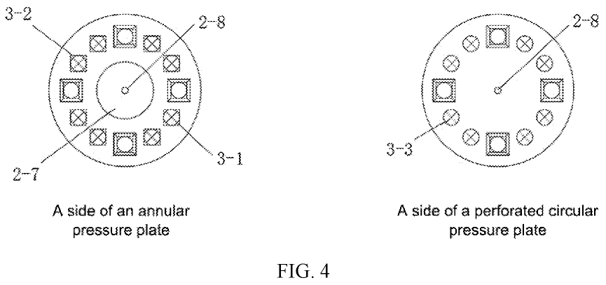

As shown in FIG. 4, the ultrasonic tomography imaging device includes eight transmitting transducers 3-1, eight transmitting amplifiers 3-2, and eight receiving transducers 3-3. The eight transmitting amplifiers 3-2 are circumferentially arranged on the outer side surface of the annular pressure plate 2-6 at angular positions of 30°, 60°, 120°, 150°, 210°, 240°, 300°, and 330°. Each transmitting transducer 3-1 overlaps and is mounted on a corresponding transmitting amplifier 3-2. The eight receiving transducers 3-3 are arranged on the outer side surface of the perforated circular pressure plate 2-15 at positions corresponding to the eight transmitting amplifiers 3-2.

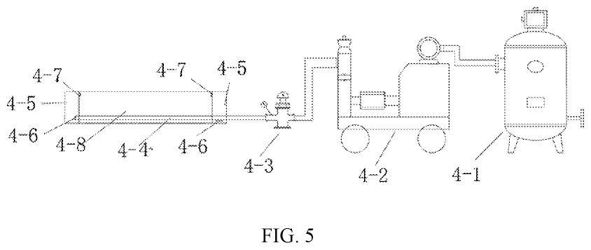

As shown in FIG. 5, the plugging device includes two plugging bags 4-5, and a plugging section 4-8 is formed between and connected to the two plugging bags 4-5. A feeding pipe 4-4 is in communication with the two plugging bags 4-5 and extends through the two plugging bags 4-5. Injection holes 4-6 are defined in portions of the feeding pipe 4-4 located within the plugging bags 4-5. Rupture valves 4-7 are oppositely arranged on surfaces of the plugging bags 4-5 and are positioned on an inner side of the plugging section 4-8. A feeding end of the feeding pipe 4-4 is sequentially connected, in order from a position closer to the two plugging bags 4-5 to a position farther away from the two plugging bags 4-5, to a first pressure-retaining valve 4-3, a constant-pressure intelligent grouting pump 4-2, and a plugging material storage tank 4-1. During plugging, slurry first fills the plugging bags 4-5 and subsequently enters the plugging section 4-8 through the rupture valves 4-7.

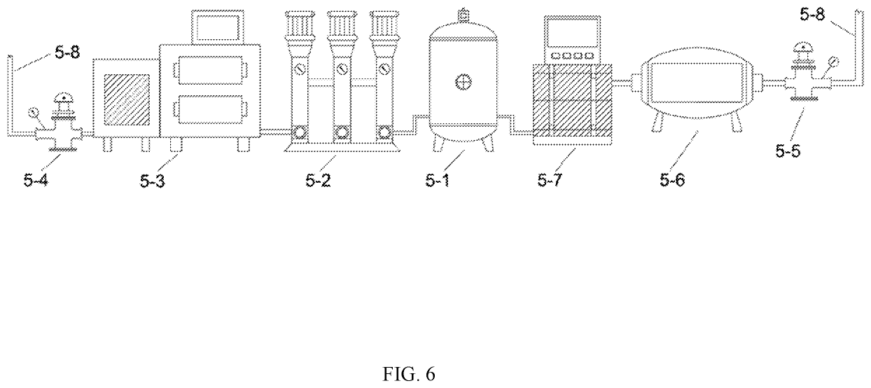

As shown in FIG. 6, the confining-pressure heating and cooling circulation device includes a second pressure-retaining valve 5-4, a confining-pressure fluid heater 5-3, a confining-pressure fluid injection pump 5-2, a confining-pressure fluid storage tank 5-1, a confining-pressure fluid cooler 5-7, an accumulator 5-6, and a third pressure-retaining valve 5-5, sequentially connected through an insulated thermal pipe 5-8. The second pressure-retaining valve 5-4 is connected to the confining-pressure fluid inlet 2-3 through the insulated thermal pipe 5-8. The third pressure-retaining valve 5-5 is connected to the confining-pressure fluid outlet 2-4 through the insulated thermal pipe 5-8. The confining-pressure fluid storage tank 5-1, the confining-pressure fluid injection pump 5-2, and the confining-pressure fluid heater 5-3 are respectively connected to a data acquisition device through control lines. The data acquisition device is electrically connected to a control system and is configured to acquire, in real time, data indicative of a remaining fluid volume in the confining-pressure fluid storage tank 5-1, a flow rate and a pressure of the confining-pressure fluid injection pump 5-2, and a temperature of the confining-pressure fluid heater 5-3, and to transmit the data to the control system. The control system dynamically adjusts operating parameters based on the acquired data so as to precisely regulate a flow rate, pressure, and temperature of the confining-pressure fluid.

In some embodiments of the present disclosure, a circular rubber gasket 2-14 is provided on an inner side surface of the first sample fixer 2-13 that contacts the coal body 6. A perforated rubber gasket 2-21 is provided on an inner side surface of the second sample fixer 2-20 that contacts the coal body 6.

In some embodiments of the present disclosure, the confining-pressure fluid injection pump 5-2 has a pressure adjustment range of 0-60 MPa and an adjustment precision of 0.10 MPa. The confining-pressure fluid heater 5-3 has a temperature control range of 0-70° C., a heating rate of ≥10 ° C./min, and a temperature control precision of 0.01° C. The second pressure-retaining valve 5-4 is connected to the second pressure-retaining valve 5-4 and has a pressure control precision of 0.01 MPa.

In some embodiments of the present disclosure, the confining-pressure fluid heater 5-3 is internally provided with a temperature measuring device configured to measure an input fluid temperature and heats the input fluid by means of an internal serpentine electric heating tube. The second pressure-retaining valve 5-4 is connected to the confining-pressure fluid heater 5-3 through the insulated thermal pipe 5-8. An output end of the second pressure-retaining valve 5-4 is connected to the confining-pressure fluid inlet 2-3 of the sample holder through the insulated thermal pipe 5-8 via a self-tightening flange.

An input end of the third pressure-retaining valve 5-5 is connected to the confining-pressure fluid outlet 2-4 of the sample holder through a self-tightening flange. The third pressure-retaining valve 5-5 has a pressure-retaining range of 0-80 MPa. The accumulator 5-6 is connected to the third pressure-retaining valve 5-5 through a high-pressure pipeline. The accumulator 5-6 is internally provided with a pre-charged flexible diaphragm bladder and is configured with a relative pressure drop of 10%-30%. The accumulator 5-6 is further connected to a multi-stage pressure-reducing valve through a high-pressure pipeline. The multi-stage pressure-reducing valve has a pressure reduction range of 0-40 MPa.

The confining-pressure fluid cooler 5-7 is internally provided with a temperature measuring device configured to measure an input fluid temperature. The confining-pressure fluid cooler 5-7 further includes a condenser pipe and a refrigerant, where the refrigerant is carbon dioxide R744. The confining-pressure fluid cooler 5-7 has a temperature control range of 0-40° C. and a cooling rate of ≥10 ° C./min. An output end of the confining-pressure fluid cooler 5-7 is connected to the confining-pressure fluid storage tank 5-1 to form a circulation loop.

### Embodiment 2

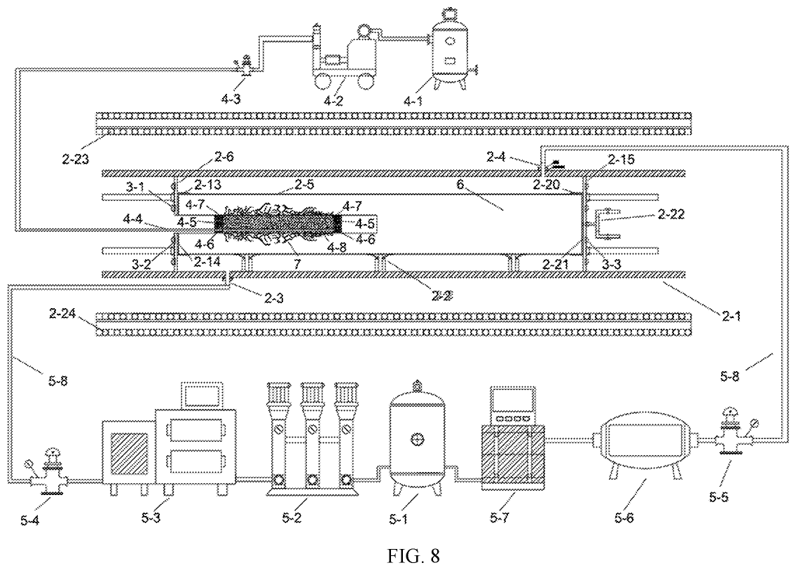

As illustrated in FIG. 7 and FIG. 8, the present disclosure further provides a method for evaluating an adaptive borehole plugging effect based on NMR, performed by the engineering bionic experimental system, the method includes the following steps:
(S1) A sample is prepared as follows: an intact coal body sample is obtained from an underground mine; the intact coal body sample is polished to match dimensions of the clamping cylinder 2-1 to obtain the coal body 6; a thermoplastic sleeve 2-5 is sleeved on the coal body 6, where a length of the thermoplastic sleeve 2-5 is greater than a length of the coal body 6; the coal body 6 wrapped in the thermoplastic sleeve 2-5 is placed into the clamping cylinder 2-1 and on the plurality of retractable sample supports 2-2; heights of the plurality of retractable sample supports 2-2 are adjusted such that both ends of the coal body 6 respectively align with the first sample fixer 2-13 and the second sample fixer 2-20; and the axial loading device is adjusted to clamp the coal body 6. The thermoplastic sleeve 2-5 is disposed on an outer surface of the coal body 6. The thermoplastic sleeve 2-5 has a temperature resistance range of 0° C. to 100° C. and a tensile strength of ≥50 MPa.
(S2) An underground simulated field is formed as follows: an axial pressing stress, a confining pressure, a gas injection amount, and a confining-pressure fluid temperature are determined according to ground stress parameters, gas content and pressure parameters, and a temperature of the underground mine; the axial loading device is activated to apply the axial pressing stress at a loading rate of 0.1 mm/min until the axial pressing stress reaches a preset pre-stress; the confining-pressure fluid injection pump 5-2 is activated to establish an initial confining pressure and inject a confining-pressure fluid; the confining-pressure fluid heater 5-3 is activated, an initial temperature t₁ of the confining-pressure fluid prior to heating is recorded, and a preliminary heating setpoint t₂ is set as a heating setpoint of the confining-pressure fluid heater 5-3 for heating the confining-pressure fluid; the confining-pressure fluid cooler 5-7 is activated and a temperature-versus-time curve of the confining-pressure fluid discharged from the confining-pressure fluid cooler 5-7 is recorded; after temperature fluctuations of the temperature-versus-time curve fall within a predetermined tolerance range, a stabilized temperature value t₃ of the temperature-versus-time curve is determined; a temperature difference Δt =t₃−t₂ is calculated and the temperature difference Δt is transmitted to a computer to calculate a heat loss; the heating setpoint of the confining-pressure fluid heater 5-3 is adjusted from the preliminary heating temperature t₂ to a calibrated heating temperature t₄ based on the heat loss, such that an internal temperature of the coal body reaches a preset temperature t₀; the axial pressing stress and the confining pressure are increased to simulate actual underground pressure conditions; and gas is introduced into the coal body through the T-shaped three-way pipe 2-22, allowing the gas to exit through the seepage hole 2-8 of the plugging cover 2-7, and gas injection is maintained for 48 hours.
(S3) Real-time dynamic imaging of fracture evolution surrounding a borehole during drilling is performed as follows: the plugging cover 2-7 is removed; the high-field NMR device is activated and, after the static magnetic field reaches a stable field strength and a magnetic field homogeneity calibration is completed, a resonance frequency, a spectral width, a number of sampling points, a number of accumulations, a relaxation delay, and a pulse sequence are set; after the high-field NMR device has operated normally for a period of time, the drilling device is activated to form the borehole along an axial center of the coal body 6; during advancement of the drill bit 1-2, the claw-type atomizing nozzle 1-3 simultaneously sprays water, and the high-field NMR device continuously acquires a T₂-weighted transverse relaxation time signal of ¹H nuclei in fracture water of the coal body surrounding the borehole, and real-time imaging is performed to visualize dynamic evolution of a fracture network surrounding the borehole; after completion of the drilling, the T₂-weighted transverse relaxation time signal of ¹H nuclei in the fracture water acquired by the high-field NMR device is recorded as a data set Q₁; the data set Q₁ is processed through image processing and three-dimensional reconstruction to obtain a three-dimensional fracture structure D₁; a maximum axial length L₀ of the fracture network is determined based on the three-dimensional fracture structure D₁; and a length L of the plugging section 4-8 is determined according to the maximum axial length L₀.
(S4) A first plugging, dynamic imaging of fracture filling surrounding the borehole, and a plugging effect evaluation are performed as follows: after completion of the drilling, openings of the borehole are sealed using the plugging cover 2-7; after sealing the openings of the borehole, the temperature of the confining-pressure fluid heater 5-3 is increased to heat the confining-pressure fluid for a period of time, thereby drying internal moisture of the coal body through thermal conduction of the confining-pressure fluid until imaging by the high-field NMR device is no longer obtainable; the two plugging bags 4-5 and the feeding pipe 4-4 are connected according to the length L of the plugging section 4-8 determined at step (S3); after connecting the two plugging bags 4-5 and the feeding pipe 4-4, the plugging cover 2-7 is removed and the two plugging bags 4-5 and the feeding pipe 4-4 are inserted into the borehole; the constant-pressure intelligent grouting pump 4-2 is activated, an initial grouting pressure is set, and a plugging material is injected into the two plugging bags 4-5 and the borehole; the high-field NMR device is monitored and, after two elliptical high-intensity NMR signal regions indicative of plugging bag inflation are formed, a grouting pressure is increased to rupture the rupture valves 4-7; after the plugging material flows into the plugging section 4-8, a constant grouting pressure is maintained and the plugging material is continuously injected until the borehole is completely filled; migrations of the plugging material within the borehole are determined through the real-time imaging; the high-field NMR device acquires a T₂-weighted transverse relaxation time signal of ¹H nuclei in water of the plugging material, and the T₂-weighted transverse relaxation time signal of ¹H nuclei in the water of the plugging material is recorded as a data set Q₂; the data set Q₂ is processed through image processing and three-dimensional reconstruction to obtain a visualized three-dimensional fracture structure D₂; the data set Q₁ is compared with the data set Q 2 to determine an overlap ratio between the data set Q₁ and the data set Q₂; and whether a ratio of the three-dimensional fracture structure D₁ to the visualized three-dimensional fracture structure D₂ falls within a tolerance range is determined according to the overlap ratio between the data set Q₁ and the data set Q₂.
(S5) Parameters of the underground simulated field are adjusted to cause the first plugging to fail and to induce generation of new fractures or propagation of pre-existing fractures surrounding the plugged borehole as follows: the ultrasonic tomography imaging device is activated; a transducer array is connected to a data acquisition module of the ultrasonic tomography imaging device; transmission parameters comprising a transmission voltage, a pulse bandwidth or waveform, an imaging speed, and a center frequency of a transducer are set; reception parameters comprising a sampling rate, a gain, and a data storage format are set; channels for bidirectional transmission are configured; the confining pressure, the axial pressing stress, and a gas pressure are adjusted to induce the generation of the new fractures or the propagation of the pre-existing fractures surrounding the plugged borehole; transmitters are activated in a predetermined sequence to perform tomographic scanning and data acquisition; propagation time and amplitude data of fracture initiation and propagation are extracted; a sound velocity distribution map is reconstructed; sound velocity anomaly regions are marked, where a spatial region is determined as a new fracture when a decrease in acoustic velocity of ≥5% is detected in the spatial region in at least three consecutive reconstructed tomographic frames acquired at a predetermined sampling frequency; two-dimensional images of all layers are stacked to form a three-dimensional voxel image; fracture structures are rendered and analyzed to obtain a three-dimensional image and a data set W₁; and ultrasonic tomography imaging data acquired by the ultrasonic tomography imaging device is transmitted to the computer.
(S6) A secondary plugging is performed as follows: the computer compares real-time NMR imaging data with the ultrasonic tomography imaging data of the new fractures transmitted at step (S5); a number of the new fractures and a void volume of apertures of the new fractures are determined by comparing the data set Q₂ and the data set W₁; an amount of a required plugging material is determined according to the number of the new fractures and the void volume of the apertures of the new fractures, so as to prevent excessive grouting pressure from inducing hydraulic fracturing of the coal body; the computer controls the plugging device to inject the required plugging material into the borehole; real-time NMR imaging is performed to visualize filling of the new fractures, the propagation of pre-existing fractures, or the fracture network, thereby acquiring the real-time NMR imaging data; the real-time NMR imaging data is compared with the ultrasonic tomography imaging data obtained at step (S5); and a plugging density is calculated to evaluate a plugging effect.
(S7) Steps (S5) and (S6) are repeated to implement an adaptive plugging process comprising plugging, plugging failure, and re-plugging under various ground stress conditions, geothermal environments, and gas pressures, thereby evaluating the adaptive borehole plugging effect.

What is claimed is:

1. An engineering bionic experimental system for evaluating an adaptive borehole plugging effect based on nuclear magnetic resonance (NMR), comprising a drilling device, a high-field NMR device, an ultrasonic tomography imaging device, a plugging device, and a confining-pressure heating and cooling circulation device, wherein:
the drilling device comprises a drill rod and a drill bit provided at one end of the drill rod;
the high-field NMR device comprises a cylindrical housing, wherein:
the cylindrical housing comprises an inner fiberglass epoxy resin tube and an outer fiberglass epoxy resin tube sleeved together, a plurality of radio-frequency coils are bonded to an outer side of the inner fiberglass epoxy resin tube and configured to generate a radio-frequency magnetic field, a plurality of gradient coils are mounted on the outer fiberglass epoxy resin tube and configured to generate a static magnetic field, and a sample holder capable of applying pressure is provided within an internal cavity of the inner fiberglass epoxy resin tube;
the sample holder comprises a clamping cylinder, wherein the clamping cylinder is hollow and non-magnetic, and both ends of the clamping cylinder are open, wherein a plurality of retractable sample supports are arranged at a lower end of a middle portion of an inner side of the clamping cylinder, a confining-pressure fluid inlet is provided at a lower portion of a left end of the clamping cylinder, and a confining-pressure fluid outlet is provided at an upper portion of a right end of the clamping cylinder;
an axial loading device for applying pressure to a coal body is mounted inside the clamping cylinder, wherein the axial loading device comprises an annular pressure plate and a perforated circular pressure plate respectively provided at both ends of the clamping cylinder;
a plugging cover is provided in a hollow portion of the annular pressure plate, wherein the plugging cover defines a seepage hole at a center of the plugging cover;
a first sample fixer is mounted on an inner side surface of the annular pressure plate, a second sample fixer is mounted on an inner side surface of the perforated circular pressure plate, and the first sample fixer and the second sample fixer are positioned at a same horizontal height;
a plurality of axial pressing rods are respectively mounted on an outer side surface of the annular pressure plate and an outer side surface of the perforated circular pressure plate; and
a T-shaped three-way pipe is threadedly connected to a center hole of the perforated circular pressure plate, and an electric throttle valve is provided on the T-shaped three-way pipe;
the ultrasonic tomography imaging device comprises a plurality of transmitting transducers, a plurality of transmitting amplifiers, and a plurality of receiving transducers, wherein the plurality of transmitting amplifiers are circumferentially and uniformly arranged on the outer side surface of the annular pressure plate, the plurality of transmitting transducers overlap and are mounted on the plurality of transmitting amplifiers, and the plurality of receiving transducers are arranged on the outer side surface of the perforated circular pressure plate at positions corresponding to the plurality of transmitting amplifiers;
the plugging device comprises two plugging bags, wherein a plugging section is provided between and connected to the two plugging bags, a feeding pipe is in communication with the two plugging bags, the feeding pipe defines injection holes in portions of the feeding pipe located within the two plugging bags, rupture valves are respectively arranged on surfaces of the two plugging bags and opposite to each other, and a feeding end of the feeding pipe is sequentially connected, in order from a position closer to the two plugging bags to a position farther away from the two plugging bags, to a first pressure-retaining valve, a constant-pressure intelligent grouting pump, and a plugging material storage tank;
the confining-pressure heating and cooling circulation device comprises a second pressure-retaining valve, a confining-pressure fluid heater, a confining-pressure fluid injection pump, a confining-pressure fluid storage tank, a confining-pressure fluid cooler, an accumulator, and a third pressure-retaining valve, sequentially connected through an insulated thermal pipe;
the second pressure-retaining valve is connected to the confining-pressure fluid inlet through the insulated thermal pipe;
the third pressure-retaining valve is connected to the confining-pressure fluid outlet through the insulated thermal pipe;
the confining-pressure fluid storage tank, the confining-pressure fluid injection pump, and the confining-pressure fluid heater are respectively connected to a data acquisition device through control lines, wherein the data acquisition device is electrically connected to a control system and is configured to acquire, in real time, data indicative of a remaining fluid volume in the confining-pressure fluid storage tank, a flow rate and a pressure of the confining-pressure fluid injection pump, and a temperature of the confining-pressure fluid heater, and to transmit the data to the control system.

2. The engineering bionic experimental system according to claim 1, wherein
the drill rod defines a central bore extending along an axial centerline of the drill rod, and has wide-tooth groove threads extending from an outer surface of the drill rod toward an interior of the drill rod;
the drill bit comprises four obliquely columnar cutters symmetrically arranged on an end surface of the drill rod, wherein a plurality of claw-type atomizing nozzles are mounted on inner sides of the four obliquely columnar cutters, and each of the plurality of claw-type atomizing nozzles has one end in communication with the central bore of the drill rod and another end facing toward a corresponding one of the four obliquely columnar cutters.

3. The engineering bionic experimental system according to claim 1, wherein
the plurality of radio-frequency coils are uniformly bonded to the outer side of the inner fiberglass epoxy resin tube, a capacitor is welded between each two adjacent radio-frequency coils among the plurality of radio-frequency coils to store energy and adjust a coil frequency, and an inductance plate, a circuit splitter, and cables are mounted in electrical communication with the plurality of radio-frequency coils;
the outer fiberglass epoxy resin tube defines annular grooves, wherein the plurality of gradient coils are uniformly attached and bonded within the annular grooves, and cooling tubes are wound around the plurality of gradient coils to absorb heat generated by the plurality of gradient coils; and
the inner fiberglass epoxy resin tube attached with the plurality of radio-frequency coils is inserted into the outer fiberglass epoxy resin tube attached with the plurality of gradient coils, and liquid nitrogen is filled and sealed in a space between the inner fiberglass epoxy resin tube and the outer fiberglass epoxy resin tube.

4. The engineering bionic experimental system according to claim 1, wherein
a first axial pressing rod, a second axial pressing rod, a third axial pressing rod, and a fourth axial pressing rod, each parallel to a central axis of the clamping cylinder, are welded onto the outer side surface of the annular pressure plate; and
a fifth axial pressing rod, a sixth axial pressing rod, a seventh axial pressing rod, and an eighth axial pressing rod, each parallel to the central axis of the clamping cylinder, are welded onto the outer side surface of the perforated circular pressure plate.

5. The engineering bionic experimental system according to claim 1, wherein a circular rubber gasket is provided on an inner side of the first sample fixer, and a perforated rubber gasket is provided on an inner side of the second sample fixer.

6. The engineering bionic experimental system according to claim 1, wherein
the plurality of transmitting transducers comprise eight transmitting transducers, the plurality of transmitting amplifiers comprise eight transmitting amplifiers, and the plurality of receiving transducers comprise eight receiving transducers;
the eight transmitting amplifiers are circumferentially arranged on an outer peripheral surface of the annular pressure plate at angular positions of 30°, 60°, 120°, 150°, 210°, 240°, 300°, and 330°; and
the eight receiving transducers are arranged on the perforated circular pressure plate at positions corresponding to the eight transmitting amplifiers.

7. The engineering bionic experimental system according to claim 1, wherein
the confining-pressure fluid injection pump has a pressure adjustment range of 0-60 MPa and an adjustment precision of 0.10 MPa;
the confining-pressure fluid heater has a temperature control range of 0-70° C., a heating rate of ≥10 ° C./min, and a temperature control precision of 0.01° C.;
the confining-pressure fluid cooler is provided internally with a temperature measuring device configured to measure an input fluid temperature; and
the confining-pressure fluid cooler is further provided internally with a condenser pipe and a refrigerant, wherein the refrigerant is carbon dioxide R744, and the confining-pressure fluid cooler has a temperature control range of 0-40° C. and a cooling rate of ≥10 ° C./min.

8. A method for evaluating an adaptive borehole plugging effect based on nuclear magnetic resonance (NMR), performed by the engineering bionic experimental system according to claim 1, comprising:
(S1) preparing a sample, comprising:
obtaining an intact coal body sample from an underground mine;
polishing the intact coal body sample to match dimensions of the clamping cylinder to obtain the coal body;
sleeving a thermoplastic sleeve on the coal body, wherein a length of the thermoplastic sleeve is greater than a length of the coal body;
placing the coal body wrapped in the thermoplastic sleeve into the clamping cylinder and on the plurality of retractable sample supports;
adjusting heights of the plurality of retractable sample supports such that both ends of the coal body respectively align with the first sample fixer and the second sample fixer; and
adjusting the axial loading device to clamp the coal body;
(S2) forming an underground simulated field, comprising:
determining an axial pressing stress, a confining pressure, a gas injection amount, and a confining-pressure fluid temperature according to ground stress parameters, gas content and pressure parameters, and a temperature of the underground mine;
activating the axial loading device to apply the axial pressing stress at a loading rate of 0.1 mm/min until the axial pressing stress reaches a preset pre-stress;
activating the confining-pressure fluid injection pump to establish an initial confining pressure and inject a confining-pressure fluid;
activating the confining-pressure fluid heater, recording an initial temperature t₁ of the confining-pressure fluid prior to heating, and setting a preliminary heating setpoint t₂ as a heating setpoint of the confining-pressure fluid heater for heating the confining-pressure fluid;
activating the confining-pressure fluid cooler and recording a temperature-versus-time curve of the confining-pressure fluid discharged from the confining-pressure fluid cooler;
after temperature fluctuations of the temperature-versus-time curve fall within a predetermined tolerance range, determining a stabilized temperature value t₃ of the temperature-versus-time curve;
calculating a temperature difference Δt=t₃−t₂ and transmitting the temperature difference Δt to a computer to calculate a heat loss;
adjusting the heating setpoint of the confining-pressure fluid heater from the preliminary heating temperature t₂ to a calibrated heating temperature t₄ based on the heat loss, such that an internal temperature of the coal body reaches a preset temperature t₀;
increasing the axial pressing stress and the confining pressure to simulate actual underground pressure conditions; and
introducing gas into the coal body through the T-shaped three-way pipe, allowing the gas to exit through the seepage hole of the plugging cover, and maintaining gas injection for 48 hours;
(S3) performing real-time dynamic imaging of fracture evolution surrounding a borehole during drilling, comprising:
removing the plugging cover;
activating the high-field NMR device and, after the static magnetic field reaches a stable field strength and a magnetic field homogeneity calibration is completed, setting a resonance frequency, a spectral width, a number of sampling points, a number of accumulations, a relaxation delay, and a pulse sequence;
after the high-field NMR device has operated normally for a period of time, activating the drilling device to form the borehole along an axial center of the coal body;
during advancement of the drill bit, continuously acquiring, by the high-field NMR device, a T₂-weighted transverse relaxation time signal of ¹H nuclei in fracture water of the coal body surrounding the borehole, and performing real-time imaging to visualize dynamic evolution of a fracture network surrounding the borehole;
after completion of the drilling, recording the T₂-weighted transverse relaxation time signal of ¹H nuclei in the fracture water acquired by the high-field NMR device as a data set Q₁;
processing the data set Q₁ through image processing and three-dimensional reconstruction to obtain a three-dimensional fracture structure D₁;
determining a maximum axial length L₀ of the fracture network based on the three-dimensional fracture structure D₁; and
determining a length L of the plugging section according to the maximum axial length L₀;
(S4) performing a first plugging, dynamic imaging of fracture filling surrounding the borehole, and a plugging effect evaluation, comprising:
after completion of the drilling, sealing openings of the borehole using the plugging cover;
after sealing the openings of the borehole, increasing the temperature of the confining-pressure fluid heater to heat the confining-pressure fluid for a period of time, thereby drying internal moisture of the coal body through thermal conduction of the confining-pressure fluid until imaging by the high-field NMR device is no longer obtainable;
connecting the two plugging bags and the feeding pipe according to the length L of the plugging section determined at step (S3);
after connecting the two plugging bags and the feeding pipe, removing the plugging cover and inserting the two plugging bags and the feeding pipe into the borehole;
activating the constant-pressure intelligent grouting pump, setting an initial grouting pressure, and injecting a plugging material into the two plugging bags and the borehole;
monitoring the high-field NMR device and, after two elliptical high-intensity NMR signal regions indicative of plugging bag inflation are formed, increasing a grouting pressure to rupture the rupture valves;
after the plugging material flows into the plugging section, maintaining a constant grouting pressure and continuously injecting the plugging material until the borehole is completely filled;
determining, through the real-time imaging, migrations of the plugging material within the borehole;
acquiring, by the high-field NMR device, a T₂-weighted transverse relaxation time signal of ¹H nuclei in water of the plugging material, and recording the T₂-weighted transverse relaxation time signal of ¹H nuclei in the water of the plugging material as a data set Q₂;
processing the data set Q₂ through image processing and three-dimensional reconstruction to obtain a visualized three-dimensional fracture structure D₂;
comparing the data set Q₁ with the data set Q₂ to determine an overlap ratio between the data set Q₁ and the data set Q₂; and
determining whether a ratio of the three-dimensional fracture structure D₁ to the visualized three-dimensional fracture structure D₂ falls within a tolerance range according to the overlap ratio between the data set Q₁ and the data set Q₂;
(S5) adjusting parameters of the underground simulated field to cause the first plugging to fail and to induce generation of new fractures or propagation of pre-existing fractures surrounding the plugged borehole, comprising:
activating the ultrasonic tomography imaging device;
connecting a transducer array to a data acquisition module of the ultrasonic tomography imaging device;
setting transmission parameters comprising a transmission voltage, a pulse bandwidth or waveform, an imaging speed, and a center frequency of a transducer;
setting reception parameters comprising a sampling rate, a gain, and a data storage format;
configuring channels for bidirectional transmission;
adjusting the confining pressure, the axial pressing stress, and a gas pressure to induce the generation of the new fractures or the propagation of the pre-existing fractures surrounding the plugged borehole;
activating transmitters in a predetermined sequence to perform tomographic scanning and data acquisition;
extracting propagation time and amplitude data of fracture initiation and propagation;
reconstructing a sound velocity distribution map;
marking sound velocity anomaly regions, wherein a spatial region is determined as a new fracture when a decrease in acoustic velocity of ≥5% is detected in the spatial region in at least three consecutive reconstructed tomographic frames acquired at a predetermined sampling frequency;
stacking two-dimensional images of all layers to form a three-dimensional voxel image;
rendering and analyzing fracture structures to obtain a three-dimensional image and a data set W₁; and
transmitting ultrasonic tomography imaging data acquired by the ultrasonic tomography imaging device to the computer;
(S6) performing a secondary plugging, comprising:
comparing, by the computer, real-time NMR imaging data with the ultrasonic tomography imaging data of the new fractures transmitted at step (S5);
determining, by comparing the data set Q₂ and the data set W₁, a number of the new fractures and a void volume of apertures of the new fractures;
determining an amount of a required plugging material according to the number of the new fractures and the void volume of the apertures of the new fractures, so as to prevent excessive grouting pressure from inducing hydraulic fracturing of the coal body;
controlling, by the computer, the plugging device to inject the required plugging material into the borehole;
performing real-time NMR imaging to visualize filling of the new fractures, the propagation of pre-existing fractures, or the fracture network, thereby acquiring the real-time NMR imaging data;
comparing the real-time NMR imaging data with the ultrasonic tomography imaging data obtained at step (S5); and
calculating a plugging density to evaluate a plugging effect;
(S7) repeating steps (S5) and (S6) to implement an adaptive plugging process comprising plugging, plugging failure, and re-plugging under various ground stress conditions, geothermal environments, and gas pressures, thereby evaluating the adaptive borehole plugging effect.
